(19) United States
(12) Patent Application Publication
(10) Pub. No.: US 2022/0217289 A1
(43) Pub. Date: Jul. 7, 2022

(54) DUAL MODE IMAGING DEVICES

(71) Applicant: SONY SEMICONDUCTOR SOLUTIONS CORPORATION, Kanagawa (JP)

(72) Inventors: Sungin HWANG, Pittsford, NY (US); Frederick BRADY, Webster, NY (US); Adarsh BASAVALINGAPPA, Fairport, NY (US); Taisuke SUWA, Auderghem (BE); Michiel TIMMERMANS, Werchter (BE)

(73) Assignee: SONY SEMICONDUCTOR SOLUTIONS CORPORATION, Kanagawa (JP)

(21) Appl. No.: 17/610,266

(22) PCT Filed: May 21, 2020
(86) PCT No.: PCT/IB2020/000393

§ 371 Date: Nov. 10, 2021

Related U.S. Application Data
(60) Provisional application No. 62/850,923, filed on May 21, 2019.

(51) Int. Cl. H04N 5/343

(52) U.S. Cl. CPC H04N 5/343; H01L 27/14636

(57) ABSTRACT

An imaging device includes a first pixel. The first pixel includes a first photoelectric conversion region, and first and second transistors coupled to the first photoelectric conversion region to transfer charge generated by the first photoelectric conversion region. The imaging device includes a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

### FIELD

Example embodiments are directed to imaging devices, imaging apparatuses, and methods for operating the same, and more particularly, to imaging devices, imaging apparatuses, and methods for image sensing.

### BACKGROUND

Image sensing has applications in many fields, including object tracking, environment rendering, etc. Some image sensors employ time-of-flight (ToF) principles to detect a distance or depth to an object or objects within a scene. In general, a ToF depth sensor includes a light source and an imaging device including a plurality of pixels for sensing reflected light. In operation, the light source emits light (e.g., infrared light) toward an object or objects in the scene, and the pixels detect the light reflected from the object or objects. The elapsed time between the initial emission of the light and receipt of the reflected light by each pixel may correspond to a distance from the object or objects. Direct ToF imaging devices may measure the elapsed time itself to calculate the distance while indirect ToF imaging devices may measure the phase delay between the emitted light and the reflected light and translate the phase delay into a distance. The depth values of the pixels are then used by the imaging device to determine a distance to the object or objects, which may be used to create a three dimensional scene of the captured object or objects.

### SUMMARY

Example embodiments relate to imaging devices, imaging apparatuses, and methods thereof that enable a ToF mode and an imaging mode with efficient wiring layouts.

At least one example embodiment is directed to an imaging device including a first pixel. The first pixel includes a first photoelectric conversion region, and first and second transistors coupled to the first photoelectric conversion region to transfer charge generated by the first photoelectric conversion region. The imaging device includes a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

According to at least one example embodiment, the first set of transfer signals include a first transfer signal applied to the first transfer transistor, and a second transfer signal applied to the second transfer transistor. The first transfer signal and the second transfer signal have different phases with respect to a reference signal.

According to at least one example embodiment, the imaging device includes a second pixel adjacent to the first pixel. The second pixel includes a second photoelectric conversion region, and third and fourth transfer transistors coupled to the second photoelectric conversion region to transfer charge generated by the second photoelectric conversion region. The first driving circuit applies a second set of transfer signals to the third and fourth transfer transistors.

According to at least one example embodiment, the second set of transfer signals include a third transfer signal applied to the third transfer transistor, and a fourth transfer signal applied to the fourth transfer transistor. Third transfer signal and the fourth transfer signal have different phases with respect to the reference signal.

According to at least one example embodiment, the second pixel is adjacent to the first pixel in a row direction, the first transfer signal and the third transfer signal have a same phase with respect to the reference signal, and the second transfer signal and the fourth transfer signal have a same phase with respect to the reference signal.

According to at least one example embodiment, the second pixel is adjacent to the first pixel in a row direction, the first transfer signal and the third transfer signal have different phases with respect to the reference signal, and the second transfer signal and the fourth transfer signal have different phases with respect to the reference signal.

According to at least one example embodiment, the imaging device includes a third pixel adjacent to the second pixel. The third pixel includes a third photoelectric conversion region, and fifth and sixth transfer transistors coupled to the third photoelectric conversion region to transfer charge generated by the third photoelectric conversion region, the first driving circuit applies the first transfer signal to the fifth transfer transistor and the second transfer signal to the sixth transfer transistor.

According to at least one example embodiment, the imaging device includes a first wiring layer including a first wiring and a second wiring. The first, second, and third pixels are arranged in a column direction in that order, the first wiring extends in the column direction to electrically connect the first transfer transistor to the fifth transfer transistor, and the second wiring extends in the column direction to electrically connect the second transfer transistor to the sixth transfer transistor.

According to at least one example embodiment, the imaging device includes a second wiring layer including a third wiring, and the third wiring extends in a row direction to electrically connect the first transfer transistor to a transfer transistor of a neighboring pixel in the row direction.

According to at least one example embodiment, the neighboring pixel is an immediately adjacent pixel in the row direction.

According to at least one example embodiment, an intervening pixel is between the first pixel and the neighboring pixel in the row direction.

According to at least one example embodiment, the imaging device includes a third wiring layer including a first contact strip that extends in the row direction and that is electrically connected to the second transfer transistor and the sixth transfer transistor.

According to at least one example embodiment, the third wiring layer includes a second contact strip that extends in the row direction and that is electrically connected to the first transfer transistor and the fifth transfer transistor.

According to at least one example embodiment, the first contact strip overlaps the first pixel, and the second contact strip overlaps the second pixel.

According to at least one example embodiment, the first wiring and the second wiring overlap the first pixel and the second pixel.

According to at least one example embodiment, the first mode is a depth mode, and the second mode is a color imaging mode.

According to at least one example embodiment, the reference signal drives a light source in the depth mode.

According to at least one example embodiment, the first driving circuit and the second driving circuit are located on opposite sides of a pixel array including the first pixel.

At least one example embodiment is directed to a system including a light source that emits light according to a drive signal, and an imaging device. The imaging device includes a first pixel including a first photoelectric conversion region, first and second transistors coupled to the first photoelectric conversion region to transfer charge generated by the first photoelectric conversion region, and a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

At least one example embodiment is directed to a pixel array including a first pixel, the first pixel including a first photoelectric conversion region, and first and second transistors coupled to the first photoelectric conversion region to transfer charge generated by the first photoelectric conversion region. The imaging device includes a first driving circuit and a second driving circuit located on opposite sides of the pixel array to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

### BRIEF DESCRIPTION OF THE FIGURES

FIG. 1 is a block diagram of an imaging device according to at least one example embodiment.

FIG. 2 illustrates an example schematic of a pixel from FIG. 1 according to at least one example embodiment.

FIG. 3 illustrates a schematic of a pixel array including a plurality of pixels according to at least one example embodiment.

FIG. 4 illustrates a comparison between inventive concepts and the related art.

FIG. 5 illustrates an example conceptual diagram for a pixel array according to at least one example embodiment.

FIG. 6 illustrates an example wiring and contact layout for four of the pixels shown in FIG. 5 according to at least one example embodiment.

FIG. 7 illustrate an example wiring layout for a column in the pixel array of FIG. 5 according to at least one example embodiment.

FIG. 8 illustrates the example wiring layout of FIG. 7 with more detail according to at least one example embodiment.

FIG. 9 illustrates an example conceptual diagram for a pixel array according to at least one example embodiment.

FIG. 10 illustrates an example wiring layout for pixels in the pixel array of FIG. 9 according to at least one example embodiment.

FIG. 11 illustrates an example wiring layout for a column in the pixel array of FIG. 9 according to at least one example embodiment.

FIG. 12 illustrates the example wiring layout of FIG. 11 with more detail according to at least one example embodiment.

FIG. 13 illustrates an example wiring layout for a column in the pixel array of FIG. 9 according to at least one example embodiment.

FIG. 14 illustrates the example wiring layout of FIG. 13 with more detail according to at least one example embodiment.

FIG. 15 illustrates an example timing diagram for driving a pixel array in a ToF mode according to at least one example embodiment.

FIG. 16 illustrates an example timing diagram for driving a pixel array in an imaging mode according to at least one example embodiment.

FIG. 17 is a block diagram illustrating an example of a ranging module according to at least one example embodiment.

FIG. 18 is a diagram illustrating use examples of an imaging device according to at least one example embodiment.

### DETAILED DESCRIPTION

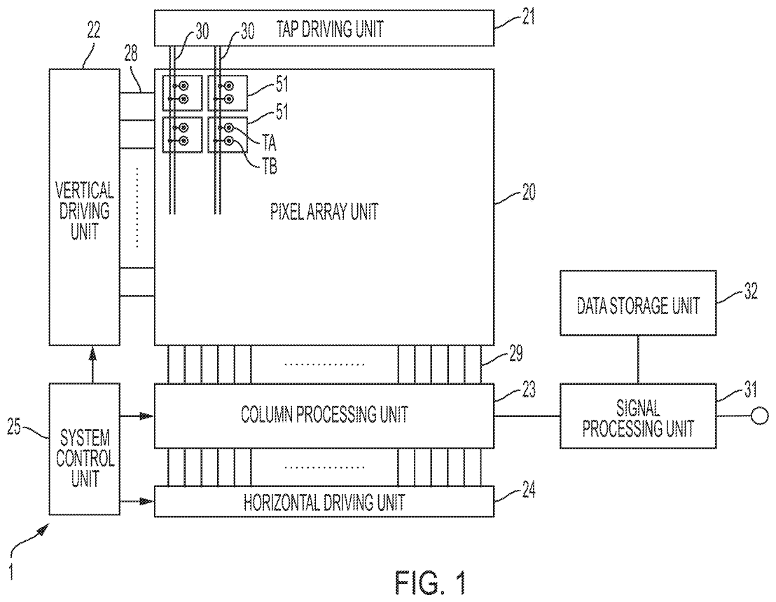

FIG. 1 is a block diagram of an imaging device according to at least one example embodiment.

The pixel 51 includes a photoelectric conversion region PD, such as a photodiode or other light sensor, transfer transistors TG0 and TG1, floating diffusion regions FD0 and FD1, reset transistors RST0 and RST1, amplification transistors AMP0 and AMP1, and selection transistors SEL0 and SEL1.

The imaging device 1 shown in FIG. 1 may be an imaging sensor of a front or rear surface irradiation type, and is provided, for example, in an imaging apparatus having a ranging function (or distance measuring function).

The imaging device 1 has a pixel array unit (or pixel array or pixel section) 20 formed on a semiconductor substrate (not shown) and a peripheral circuit integrated on the same semiconductor substrate the same as the pixel array unit 20. The peripheral circuit includes, for example, a tap driving unit (or tap driver) 21, a vertical driving unit (or vertical driver) 22, a column processing unit (or column processing circuit) 23, a horizontal driving unit (or horizontal driver) 24, and a system control unit (or system controller) 25.

The imaging device element 1 is further provided with a signal processing unit (or signal processor) 31 and a data storage unit (or data storage or memory or computer readable storage medium) 32. Note that the signal processing unit 31 and the data storage unit 32 may be mounted on the same substrate as the imaging device 1 or may be disposed on a substrate separate from the imaging device 1 in the imaging apparatus.

The pixel array unit 20 has a configuration in which pixels 51 that generate charge corresponding to a received light amount and output a signal corresponding to the charge are two-dimensionally disposed in a matrix shape of a row direction and a column direction. That is, the pixel array unit 20 has a plurality of pixels 51 that perform photoelectric conversion on incident light and output a signal corresponding to charge obtained as a result. Here, the row direction refers to an arrangement direction of the pixels 51 in a horizontal direction, and the column direction refers to the arrangement direction of the pixels 51 in a vertical direction. The row direction is a horizontal direction in the figure, and the column direction is a vertical direction in the figure.

The pixel 51 receives light incident from the external environment, for example, infrared light, performs photoelectric conversion on the received light, and outputs a pixel signal according to charge obtained as a result. The pixel 51 may include a first charge collector that detects charge obtained by the photoelectric conversion PD by applying a predetermined voltage (first voltage) to the pixel 51, and a second charge collector that detects charge obtained by the photoelectric conversion by applying a predetermined voltage (second voltage) to the pixel 51. The first and second charge collector may include tap A and tap B, respectively. Although two charge collectors are shown (i.e., tap A, and tap B), more or fewer charge collectors may be included according to design preferences. The first voltage and the second voltage may be applied to respective areas of the pixel near tap A and tap B to assist with channeling charge toward tap A and tap B during different time periods. The charge is then read out of each tap A and B with transfer signals GD.

Although FIG. 1 illustrates two taps A/B, it should be appreciated that more or fewer taps and charge collectors may be included if desired, which may result in additional signal lines not shown in FIG. 1.

The tap driving unit 21 supplies the predetermined first voltage to the first charge collector of each of the pixels 51 of the pixel array unit 20 through a predetermined voltage supply line 30, and supplies the predetermined second voltage to the second charge collector thereof through the predetermined voltage supply line 30. Therefore, two voltage supply lines 30 including the voltage supply line 30 that transmits the first voltage and the voltage supply line 30 that transmits the second voltage are wired to one pixel column of the pixel array unit 20.

In the pixel array unit 20, with respect to the pixel array of the matrix shape, a pixel drive line 28 is wired along a row direction for each pixel row, and two vertical signal lines 29 are wired along a column direction for each pixel column. For example, the pixel drive line 28 transmits a drive signal for driving when reading a signal from the pixel. Note that, although FIG. 1 shows one wire for the pixel drive line 28, the pixel drive line 28 is not limited to one. One end of the pixel drive line 28 is connected to an output end corresponding to each row of the vertical driving unit 22.

The vertical driving unit 22 includes a shift register, an address decoder, or the like. The vertical driving unit 22 drives each pixel of all pixels of the pixel array unit 20 at the same time, or in row units, or the like. That is, the vertical driving unit 22 includes a driving unit that controls operation of each pixel of the pixel array unit 20, together with the system control unit 25 that controls the vertical driving unit 22.

The signals output from each pixel 51 of a pixel row in response to drive control by the vertical driving unit 22 are input to the column processing unit 23 through the vertical signal line 29. The column processing unit 23 performs a predetermined signal process on the pixel signal output from each pixel 51 through the vertical signal line 29 and temporarily holds the pixel signal after the signal process.

Specifically, the column processing unit 23 performs a noise removal process, a sample and hold (S/H) process, an analog to digital (AD) conversion process, and the like as the signal process.

The horizontal driving unit 24 includes a shift register, an address decoder, or the like, and sequentially selects unit circuits corresponding to pixel columns of the column processing unit 23. The column processing unit 23 sequentially outputs the pixel signals obtained through the signal process for each unit circuit, by a selective scan by the horizontal driving unit 24.

The system control unit 25 includes a timing generator or the like that generates various timing signals and performs drive control on the tap driving unit 21, the vertical driving unit 22, the column processing unit 23, the horizontal driving unit 24, and the like, on the basis of the various generated timing signals.

The signal processing unit 31 has at least a calculation process function and performs various signal processing such as a calculation process on the basis of the pixel signal output from the column processing unit 23. The data storage unit 32 temporarily stores data necessary for the signal processing in the signal processing unit 31. The signal processing unit 31 may control overall functions of the imaging device 1. For example, the tap driving unit 21, the vertical driving unit 22, the column processing unit 23, the horizontal driving unit 24, and the system control unit 25, and the data storage unit 32 may be under control of the signal processing unit 31. The signal processing unit or signal processor 31, alone or in conjunction with the other elements of FIG. 1, may control all operations of the systems discussed in more detail below with reference to the accompanying figures. Thus, the terms “signal processing unit” and “signal processor” may also refer to a collection of elements 21, 22, 23, 24, 25, and/or 31. A signal processor according to at least one example embodiment is capable of processing color information to produce a color information and depth information to produce a depth image.

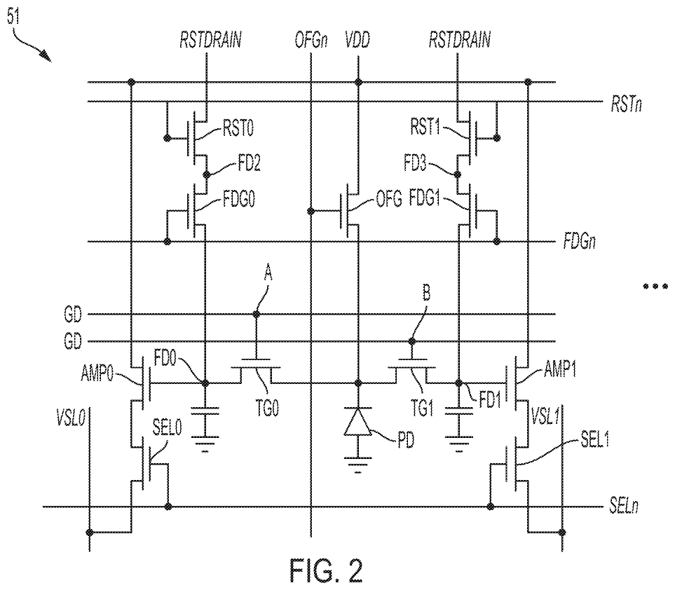

FIG. 2 illustrates an example schematic of a pixel 51 from FIG. 1. The pixel 51 includes a photoelectric conversion region PD, such as a photodiode or other light sensor, transfer transistors TG0 and TG1, floating diffusion regions FD0 and FD1, reset transistors RST0 and RST1, amplification transistors AMP0 and AMP1, and selection transistors SEL0 and SEL1. The pixel 51 may further include an overflow transistor OFG, transfer transistors FDG0 and FDG1, and floating diffusion regions FD2 and FD3.

The pixel 51 may be driven according to control signals or transfer signals GD applied to gates or taps A/B of transfer transistors TG0/TG1, reset signal RSTDRAIN, overflow signal OFGn, power supply signal VDD, selection signal SELn, and vertical selection signals VSL0 and VSL1. These signals are provided by various elements from FIG. 1, for example, the tap driver 21, vertical driver 22, system controller 25, etc.

As shown in FIG. 2, the transfer transistors TG0 and TG1 are coupled to the photoelectric conversion region PD and have taps A/B that transfer charge as a result of applying transfer signals.

These transfer signals GD may have different phases relative to a phase of a modulated signal from a light source (e.g., phases that differ 0 degrees, 90 degrees, 180 degrees, and/or 270 degrees, or alternatively, phases that differ by 120 degrees). The transfer signals may be applied in a manner that allows for depth information (or pixel values) to be captured in a desired number of frames (e.g., one frame, two frames, four frames, etc.). One of ordinary skill in the art would understand how to apply the transfer signals in order to use the collected charge to calculate a distance to an object. In at least one example embodiment, other transfer signals may be applied in a manner that allows for color information to be captured for a color image.

It should be appreciated that the transfer transistors FDG0/FDG1 and floating diffusions (or floating diffusion extensions) FD2/FD3 are included to expand the charge capacity of the pixel 51, if desired. However, these elements may be omitted or not used, if desired. The overflow transistor OFG is included to transfer overflow charge from the photoelectric conversion region PD, but may be omitted or unused if desired. Further still, if only one tap is desired, then elements associated with the other tap may be unused or omitted (e.g., TG1, FD1, FDG1, RST1, SEL1, AMP1).

Here, it should be appreciated that the pixel 51 includes identical sets of pixel elements that may be further replicated for each pixel 51 if desired. For example, elements TG0, FD0, FDG0, FD2, RST0, SEL0, AMP0, VSL0 are considered as a first set of pixel elements, while TG1, FD1, FDG1, FD3, RST1, SEL1, AMP1, and VSL1 are a second set of pixel elements that have the same structures, connections to one another, and functions as those in the first set of pixel elements. N sets of pixel elements TGn, FDn, FDGn, RSTn, SELn, AMPn, and VSLn may be included as indicated by the ellipsis in FIG. 2.

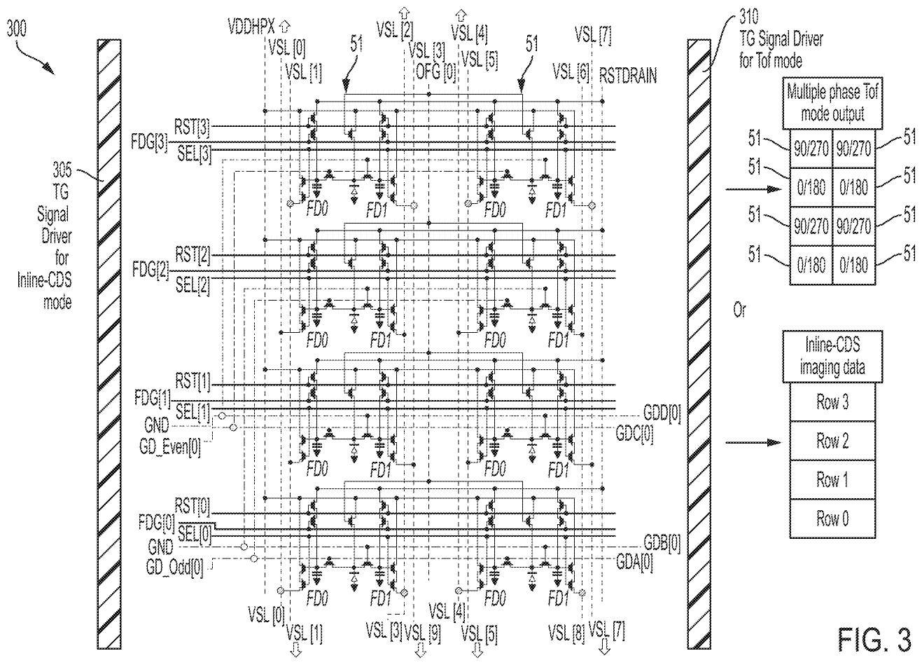

Example embodiments will now be described with reference to FIGS. 3-15, which relate to pixel layouts and driving methods thereof that may reduce a footprint of a pixel, allow for substantially same charge transfer times for transfer transistors, provide improved depth sensing performance in bright ambient light conditions, and/or provide various operational modes.

It should be further understood that FIGS. 3-14 show substantially accurate relative positional relationships of the elements depicted therein and can be relied upon as support for such positional relationships. For example, the figures provide support for selection transistors SEL and amplification transistors AMP being aligned with one another in a vertical direction, while transistors FDG and RST are aligned with one another in the vertical direction. As another example, the figures provide support for a transistor on a right side of a figure being aligned with a transistor on a left side of a figure in the horizontal direction. As yet another example, the figures are generally accurate with respect to showing positions of overlapping elements.

In addition, where reference to general element or set of elements is appropriate instead of a specific element, the description may refer to the element or set of elements by its root term. For example, when reference to a specific transfer transistor TG0 or TG1 is not necessary, the description may refer to the transfer transistor(s) “TG.”

FIG. 3 illustrates inventive concepts according to at least one example embodiment. In more detail, FIG. 3 illustrates a schematic 300 of a pixel array including a plurality of pixels 51. As shown, the imaging device 1 may include an imaging signal driver or driving circuit 305 for an imaging mode (e.g., an inline correlated double sampling (inline CDS) mode) to generate a color image and a ToF signal driver or driving circuit 310 for a ToF or depth mode to generate a depth map. The signal drivers 305/310 may provide transfer signals GD, GD, GD, GD to transfer transistors TG0 and TG1 of the pixels 51, and be included in one or more of the elements depicted in FIG. 1. As shown in FIG. 3, however, the drivers 305/310 are on opposite sides of the pixel array in order to allow for connection to both sides of each signal line. In the imaging mode, the imaging device 1 may output image signals to generate a color image while in the ToF mode, the imaging device 1 may output image signals to generate a depth image. In the ToF mode, the transfer signals GD are applied to respective gates of transfer transistors TG0/TG1 at phases that have a desired relationship to a reference optical signal that is emitted toward an object and reflected back from the object to the pixels. Here, it should be appreciated that pixels 51 in the pixel array include color filters arranged in a Bayer pattern, or color filters arranged in a Bayer pattern where one of the green color filters is a neutral color filter (white, gray, or black color filter). In order to sense infrared (IR) light for the depth mode, each pixel 51 is formed without an IR-cut filter.

FIG. 3 further illustrates various signal lines connected to the elements of each pixel and the drivers 305/10. These signal lines include reset signal lines RST[0, 1, 2, 3,], vertical signal lines VSL[0, 1, 2, 3, 4, 5, 6, 7, 8, 9], transfer signal lines FDG [0, 1, 2, 3], transfer signal lines GDA[0], GDB[0] (with connections GD_Odd[0] to pixels in odd row numbers and GD_Even[0] to pixels in even row numbers), power signal lines VDDHPX and RSTDRAIN, ground signal lines GND to ground an unused transfer transistor TG, and signal lines OFG connected to gates of overflow transistors OFG. In an imaging mode, imaging driver 810 may apply signals to these signal lines, while in a depth mode, the depth driver 815 may apply signals to the signal lines.

In the ToF mode, the ToF driver 310 may provide even and odd rows with different transfer signals GD. For example, the ToF driver 310 may provide transfer signals GDC and GDD to respective transfer transistors TG0/TG1 in an odd row at phase shifts of 90 and 270 degrees with respect to a reference optical signal, and the ToF driver 310 may provide transfer signals GDA and GDB to respective transfer transistors TG0/TG1 in an even row at phase shifts of 0 and 180 degrees with respect to the reference optical signal. This driving method may provide enough data for depth computations from a single exposure. One method for calculating distance is an object is set forth below with Equation (1):

$$Distance = \frac{C \cdot Δ T}{2} = \frac{C \cdot α}{4 π {f}_{mod}} \\ α = arctan ( \frac{{ϕ}_{1} - {ϕ}_{3}}{{ϕ}_{0} - {ϕ}_{2}} ) \qquad ( 1 )$$

Here, C is the speed of light, ΔT is the time delay, fmod is the modulation frequency of the emitted light or reference optical signal, φ0 to φ3 are the signal values detected with transfer signals having phase differences from the emitted light 0 degrees, 90 degrees, 180 degrees, and 270 degrees, respectively.

In the imaging mode, the imaging signal driver 305 may provide transfer signals to rows 0, 1, 2, 3 of the pixels 51. Here, only one transfer transistor TG0 or TG1 per pixel 51 may be receive a transfer signal (vs. two transfer transistors receiving transfer signals with different phases in the ToF mode).

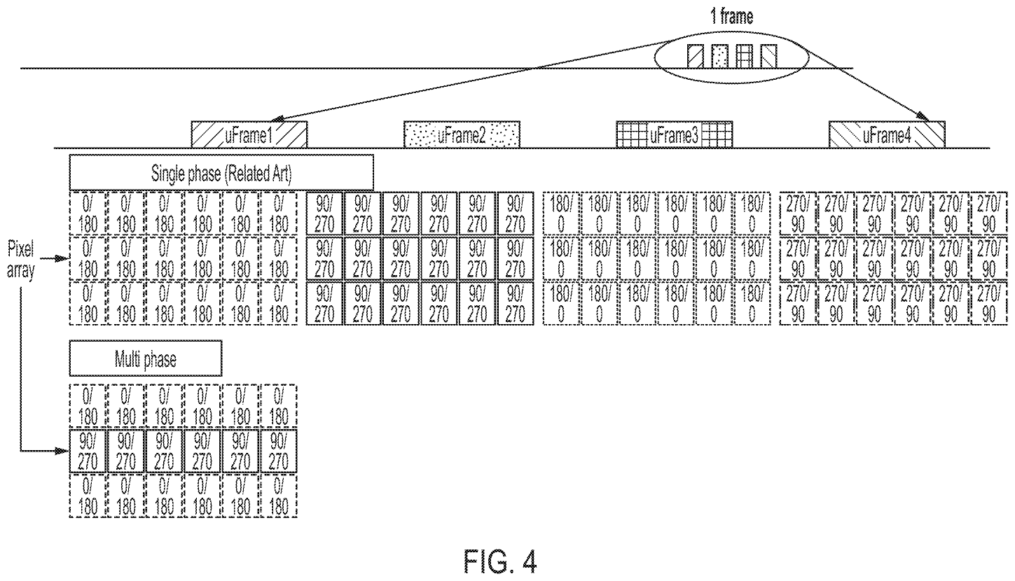

FIG. 4 illustrates a comparison between inventive concepts and the related art. As shown, inventive concepts employ a multi-phase driving method for a pixel array that may obtain a depth map in one subframe (μframe) of a frame compared to a related art method that obtains a depth map over the course of four subframes.

FIG. 5 illustrates an example conceptual diagram 500 for a pixel array according to at least one example embodiment. Each block in FIG. 5 represents a pixel 51 in the pixel array. As shown, the pixels 51 are arranged in columns and rows, and each pixel 51 includes a designation of 90/270 or 0/180 to indicate the phase of transfer signal applied to TG0 and TG1. In general, a designation of 90/270 means that the transfer transistor TG0 of a pixel 51 receives a transfer signal that is 90 degrees out of phase with the reference optical signal while the transfer transistor TG1 of the same pixel 51 receives a transfer signal that is 270 degrees out of phase with the reference optical signal. As shown in FIG. 5, the same two sets of phases may be applied to an entire row of pixels in the array.

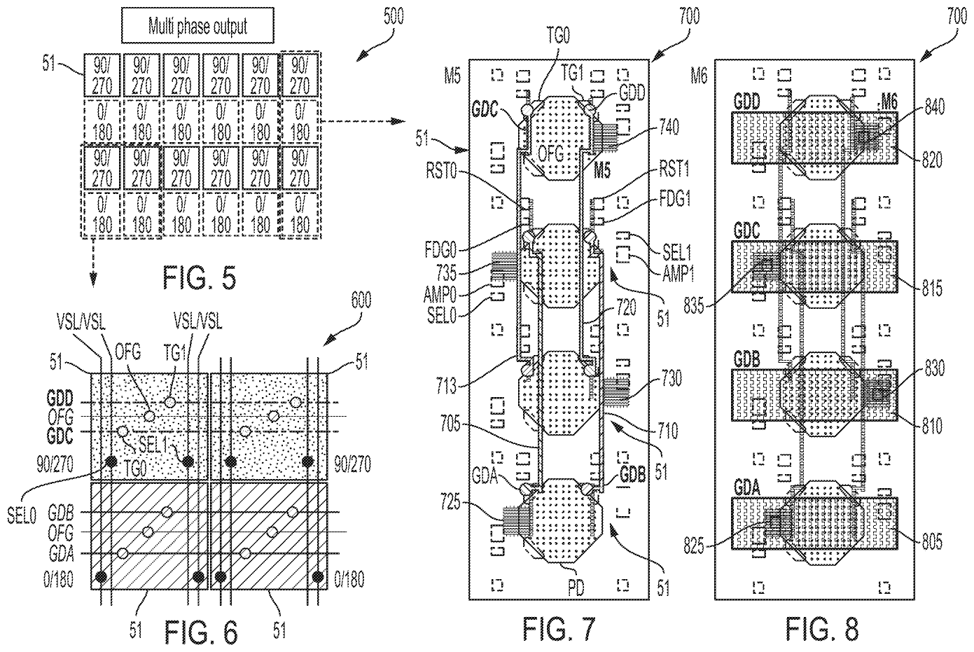

FIG. 6 illustrates an example wiring and contact layout 600 for a 2×2 group of four of the pixels 51 shown in FIG. 5. Contacts (illustrated with circles) for wirings that receive transfer signals GDD, GDC, GDB, and GDA are included for respective transfer transistors TG0/TG1 and have the locations shown in FIG. 6. FIG. 6 further illustrates locations of contacts and wirings for transistors OFGs and vertical signal lines VSL, where the vertical signal lines VSL are connected to respective selection transistors SEL as in FIG. 3. As can be appreciated from FIG. 6, contacts for transistors TG0, TG1, and OFG for each pixel 51 are spaced apart from one another at regular intervals in the horizontal and vertical directions. In addition, the contacts of a pixel 51 are aligned with corresponding contacts of another pixel 51 in the horizontal and vertical directions. For example, the contact for transfer transistor TG0 of one pixel 51 is aligned with the contact for transfer transistor TG0 of a horizontally adjacent pixel 51 and the contact for transfer transistor TG0 of a vertically adjacent pixel 51. The same is true for contacts of selection transistors SEL0 and SEL1, transistors OFG, and transfer transistors TG1. The wirings shown in FIG. 6 may be in an M3 level wiring of the imaging device 1.

FIGS. 7 and 8 illustrate an example wiring layout 700 for a column in the pixel array of FIG. 5. For example, FIG. 7 illustrates an example wiring layout 700 including wirings 705, 710, 715, and 720 for connecting transfer transistors TG of two different pixels 51 to one another in an M5 wiring level of the imaging device 1. The wirings 705, 710, 715, and 720 generally extend in a vertical direction, and receive transfer signals GDA/GDB/GDC/GDD as shown.

FIG. 7 further illustrates contact pads 725, 730, 735, and 740 electrically connected to wirings 705, 710, 715, and 720, respectively. As shown the contact pads 725 and 735 are on a same side of a respective pixel 51 while contact pads 730 and 740 are on an opposite side of a respective pixel 51.

FIG. 8 illustrates an M6 wiring layer including contact strips 805, 810, 815, and 820 that are electrically connected to contact pads 725, 730, 735, and 740, respectively, by vias 825, 830, 835, and 840. The contact pads 725, 730, 735, and 740 receive transfer signals GDA, GDB, GDC, and GDD, respectively.

FIGS. 7 and 8 further illustrate layouts of each pixel 51 including transistors TG, OFG, SEL, RST, and AMP electrically connected to one another as shown in the schematics of FIGS. 2 and 3. In FIGS. 7 and 8, transistors TG0 and TG1 are on a same side of a photoelectric conversion region PD while the transistor OFG is on an opposite side of the photoelectric conversion region PD.

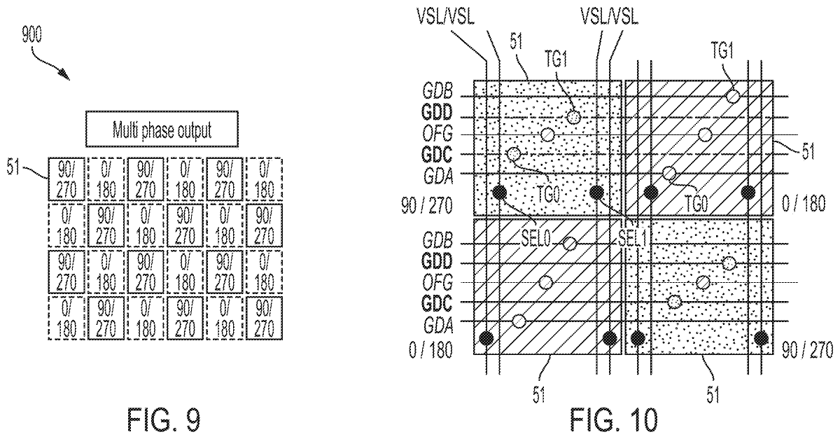

FIG. 9 illustrates an example conceptual diagram 900 for a pixel array according to at least one example embodiment. FIG. 10 illustrates an example wiring layout for pixels in the pixel array of FIG. 9. As shown, each row of pixels 51 includes at least five horizontal signal lines for connected to transfer transistors of the pixels (e.g., TGs and OFGs), and four vertical signal lines VSLs for connecting to selection transistors SELs of the pixels 51. As in FIG. 5, circles represent contacts that are electrically connected to transfer transistors TG0/TG1, transistor OFG, and selections transistors SEL, and receive transfer signals GDA, GDB, GDC, and GDD.

As can be appreciated from FIG. 10, contacts for transistors TG0, TG1, and OFG for each pixel 51 are spaced apart from one another at regular intervals in the horizontal and vertical directions. In addition, the contacts of a pixel 51 are aligned with corresponding contacts of another pixel 51 in the horizontal and vertical directions. For example, the contact for transfer transistor TG0 of one pixel 51 is aligned with the contact for transfer transistor TG0 of a horizontally adjacent pixel 51 and the contact for transfer transistor TG0 of a vertically adjacent pixel 51. The same is true for contacts of selection transistors SEL0 and SEL1, transistors OFG, and transfer transistors TG1. The wirings shown in FIG. 10 may be in an M3 level wiring of the imaging device 1.

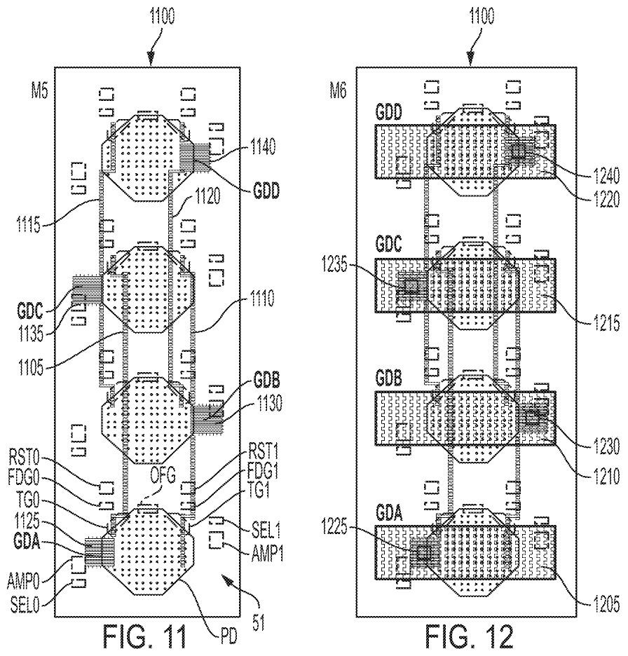

FIGS. 11 and 12 illustrate an example wiring layout 1100 for a column in the pixel array of FIG. 9 according to at least one example embodiment. FIGS. 11 and 12 are similar to FIGS. 7 and 8 except that FIGS. 11 and 12 illustrate that the transistor OFG and transfer transistors TGs of each pixel 51 are on a same side of the photoelectric conversion region PD. FIGS. 11 and 12 may be applied to the pixel array of FIG. 5 if desired. As in FIGS. 7 and 8, the layout 1100 illustrates wirings 1105, 1110, 1115, and 1120 that electrically connect with respective contact pads 1125, 1130, 1135, and 1140 in an M5 wiring layer. The contact pads 1125, 1130, 1135, and 1140 electrically connect to contact strips 1205, 1210, 1215, and 1220, respectively, located in an M6 wiring layer using vias 1125, 1230, 1235, and 1240.

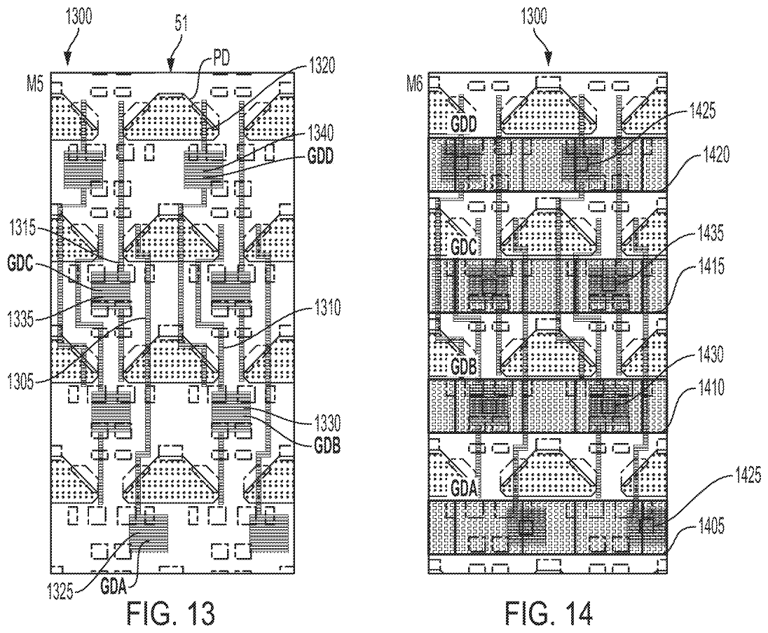

FIGS. 13 and 14 illustrate an example wiring layout 1300 for a pixel array according to at least one example embodiment. FIGS. 13 and 14 are the same as FIGS. 11 and 12 except that the photoelectric conversion regions PD in FIGS. 13 and 14 are smaller than in FIGS. 11 and 12 and the pixel transistor configurations are different. The layout 1300 may be applied to the pixel arrays of FIGS. 5 and 9. As in FIGS. 7, 8, 11, and 12, FIGS. 13 and 14 show M5 wiring layer wirings 1305, 1310, 1315, 1320 electrically connected to respective contact pads 1325, 1330, 1335, and 1340, as well as M6 wiring layer contact strips 1405, 1410, 1415, and 1420 electrically connected to contact pads with vias 1425, 1430, 1435, and 1440. FIGS. 13 and 14 further show how the wirings, contact pads, and contact strips are laid out for two columns of pixels 51. The pattern for two columns of pixels 51 may be applied to the entire pixel array, and the same pattern may be used for the layouts of FIGS. 7, 8, 11, and 12.

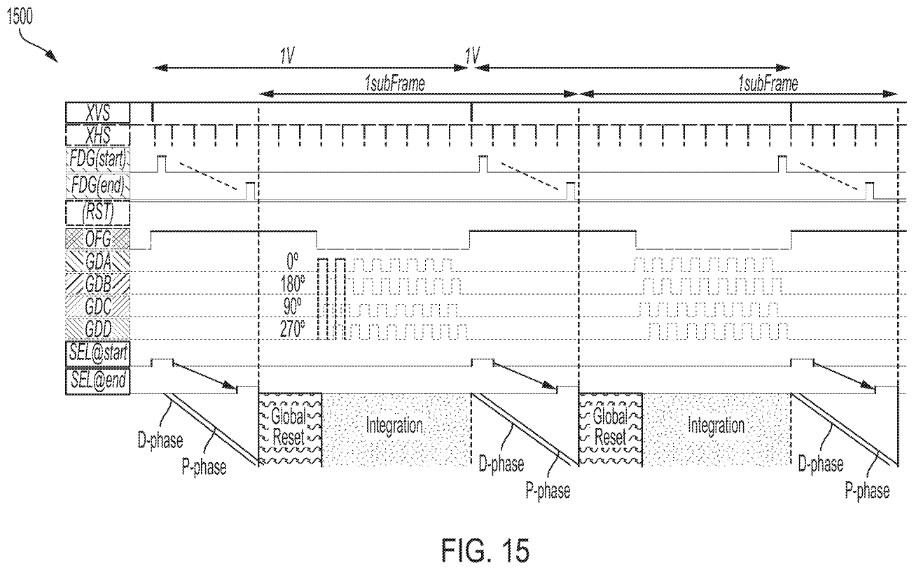

FIG. 15 illustrates an example timing diagram 1500 for driving a pixel array in a ToF mode according to at least one example embodiment. As shown, the transfer signals GDA, GDB, GDC, and GDD are applied to respective transfer transistors TG0 and TG1 with phases having a relationship to a reference optical signal (e.g., 0, 90, 180, and 270 degrees phase shifts with respect to the reference optical signal). FIG. 15 further illustrates a horizontal synchronization signal XHS to signify lines of a frame, and a vertical synchronization signal XVS to signify whole frames. As shown, the signals of interest are transferred from photoelectric conversion regions to floating diffusions FD during an integration period (labeled Integration) within a subframe that begins with a global reset operation and terminates at the beginning of D-phase/P-phase readout (where the D-phase readout corresponds to reading out reset levels of electric charge from the PD while the P-phase readout corresponds to reading out actual exposure levels of electric charge from the PD). A difference between the P-phase readout and the D-phase readout may correspond to the total level of charge collected by a PD during the subframe. The timing diagram of FIG. 15 may apply to an entire pixel array at a same time. That is, FIG. 15 represents a global operation for driving a pixel array in a ToF mode to gather depth information and generate a depth map or depth image in accordance with known techniques.

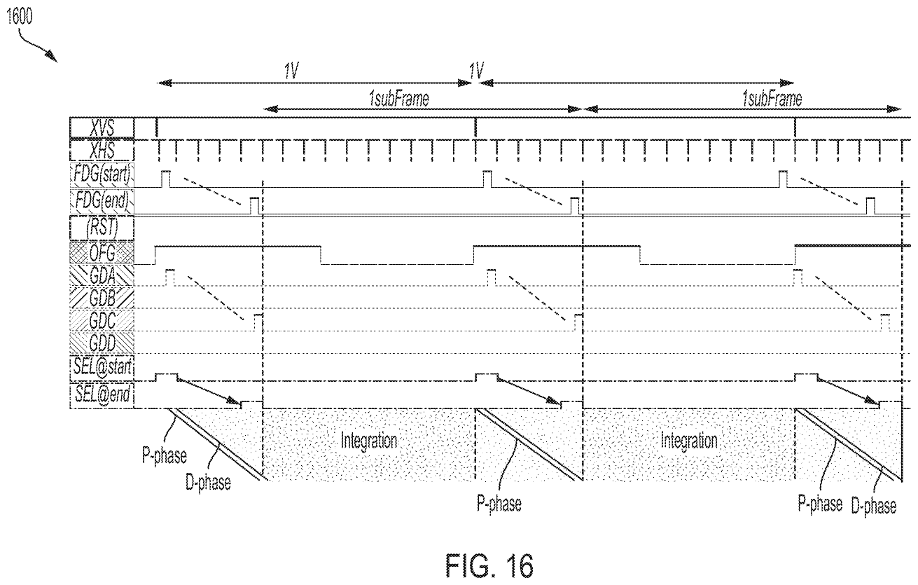

FIG. 16 illustrates an example timing diagram for driving a pixel array in an imaging mode according to at least one example embodiment. Here, it should be understood that transfer signals GDB and GDD (or alternatively, GDA and GDC) are not active so that each pixel utilizes only one transfer transistor TG to transfer charge from a photoelectric conversion region to a floating diffusion. The timing diagram of FIG. 16 may be applied to a pixel array row-by-row in order to gather color information and generate a color image in accordance with known techniques.

With reference to FIGS. 3-16, it should be appreciated that example embodiments are not limited to the patterns and layouts shown therein, and may vary according to design preferences. In addition, it should be appreciated that other wiring layers of an imaging device may exist but are not shown in detail here.

Systems/devices that may incorporate the above described imaging devices will now be described.

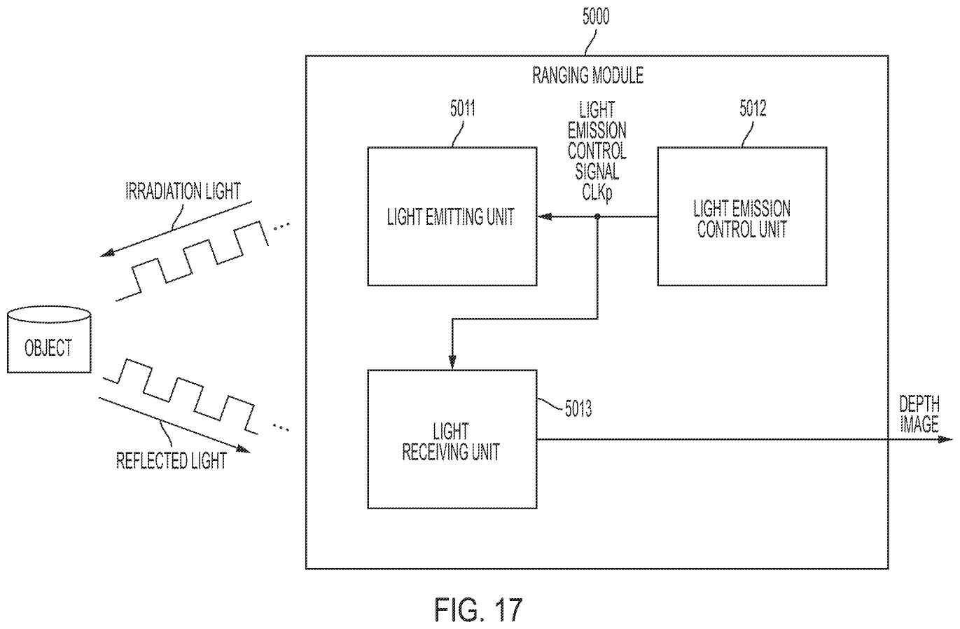

FIG. 17 is a block diagram illustrating an example of a ranging module according to at least one example embodiment.

The ranging module 5000 includes a light emitting unit 5011, a light emission control unit 5012, and a light receiving unit 5013.

The light emitting unit 5011 has a light source that emits light having a predetermined wavelength, and irradiates the object with irradiation light of which brightness periodically changes. For example, the light emitting unit 5011 has a light emitting diode that emits infrared light having a wavelength in a range of 780 nm to 1000 nm as a light source, and generates the irradiation light in synchronization with a light emission control signal CLKp of a rectangular wave supplied from the light emission control unit 5012.

Note that, the light emission control signal CLKp is not limited to the rectangular wave as long as the control signal CLKp is a periodic signal. For example, the light emission control signal CLKp may be a sine wave.

The light emission control unit 5012 supplies the light emission control signal CLKp to the light emitting unit 5011 and the light receiving unit 5013 and controls an irradiation timing of the irradiation light. A frequency of the light emission control signal CLKp is, for example, 20 megahertz (MHz). Note that, the frequency of the light emission control signal CLKp is not limited to 20 megahertz (MHz), and may be 5 megahertz (MHz) or the like.

The light receiving unit 5013 receives reflected light reflected from the object, calculates the distance information for each pixel according to a light reception result, generates a depth image in which the distance to the object is represented by a gradation value for each pixel, and outputs the depth image.

The above-described imaging device 1 is used for the light receiving unit 5013, and for example, the imaging device 1 serving as the light receiving unit 5013 calculates the distance information for each pixel from a signal intensity detected by each tap, on the basis of the light emission control signal CLKp.

As described above, the imaging device 1 shown in FIG. 1 is able to be incorporated as the light receiving unit 5013 of the ranging module 5000 that obtains and outputs the information associated with the distance to the subject by the indirect ToF method. By adopting the imaging device 1 of one or more of the embodiments described above, it is possible to improve one or more distance measurement characteristics of the ranging module 5000 (e.g., distance accuracy, speed of measurement, and/or the like).

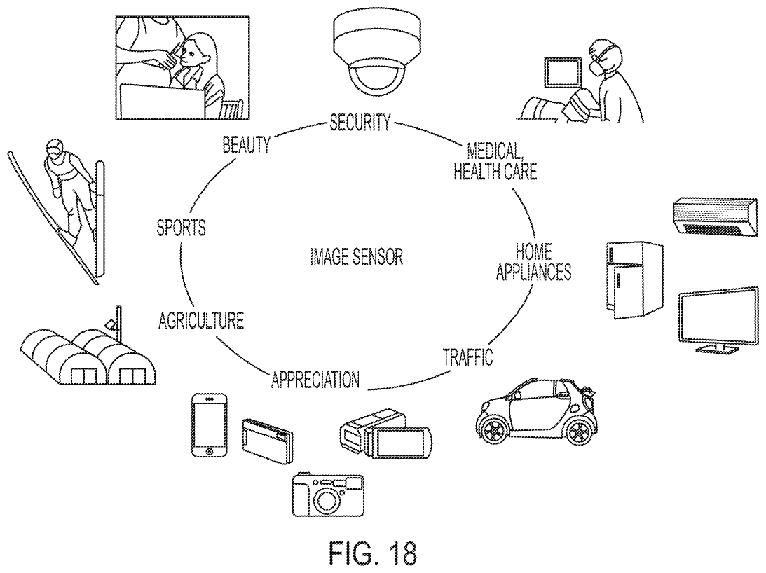

FIG. 18 is a diagram illustrating use examples of an imaging device 1 according to at least one example embodiment.

For example, the above-described imaging device 1 (image sensor) can be used in various cases of sensing light such as visible light, infrared light, ultraviolet light, and X-rays as described below. The imaging device 1 may be included in apparatuses such as a digital still camera and a portable device with a camera function which capture images, apparatuses for traffic such as an in-vehicle sensor that captures images of a vehicle to enable automatic stopping, recognition of a driver state, measuring distance, and the like. The imaging device 1 may be included in apparatuses for home appliances such as a TV, a refrigerator, and an air-conditioner in order to photograph a gesture of a user and to perform an apparatus operation in accordance with the gesture. The imaging device 1 may be included in apparatuses for medical or health care such as an endoscope and an apparatus that performs angiography through reception of infrared light. The imaging device 1 may be included in apparatuses for security such as a security monitoring camera and a personal authentication camera. The imaging device 1 may be included in an apparatus for beauty such as a skin measuring device that photographs skin. The imaging device 1 may be included in apparatuses for sports such as an action camera, a wearable camera for sports, and the like. The imaging device 1 may be included in apparatuses for agriculture such as a camera for monitoring a state of a farm or crop.

Example embodiments will now be described with reference to FIGS. 1-18.

At least one example embodiment is directed to an imaging device 1 including a first pixel 51. The first pixel 51 includes a first photoelectric conversion region PD, and first and second transistors TG0/TG1 coupled to the first photoelectric conversion region PD to transfer charge generated by the first photoelectric conversion region PD. The imaging device 1 includes a first driving circuit 310 and a second driving circuit 305 to drive the first pixel 51 in a first mode and a second mode, the first mode being a mode in which the first driving circuit 310 applies a first set of transfer signals to the first and second transfer transistors TG0/TG1, the second mode being a mode in which the second driving circuit 305 applies a transfer signal to only one of the first and second transfer transistors TG0/TG1.

According to at least one example embodiment, the first set of transfer signals include a first transfer signal GD applied to the first transfer transistor TG0, and a second transfer signal GD applied to the second transfer transistor TG1. The first transfer signal GD and the second transfer signal GD have different phases with respect to a reference signal (e.g., a drive signal that drives a light source).

According to at least one example embodiment, the imaging device 1 includes a second pixel 51 adjacent to the first pixel 51. The second pixel 51 includes a second photoelectric conversion region PD, and third and fourth transfer transistors TG0/TG1 coupled to the second photoelectric conversion region PD to transfer charge generated by the second photoelectric conversion region PD. The first driving circuit 310 applies a second set of transfer signals to the third and fourth transfer transistors TG0/TG1.

According to at least one example embodiment, the second set of transfer signals include a third transfer signal GD applied to the third transfer transistor TG0, and a fourth transfer signal GD applied to the fourth transfer transistor TG1. Third transfer signal GD and the fourth transfer signal GD have different phases with respect to the reference signal.

According to at least one example embodiment, the second pixel 51 is adjacent to the first pixel 51 in a row direction, the first transfer signal GD and the third transfer signal GD have a same phase with respect to the reference signal, and the second transfer signal and the fourth transfer signal have a same phase with respect to the reference signal (see FIG. 5).

According to at least one example embodiment, the second pixel 51 is adjacent to the first pixel 51 in a row direction, the first transfer signal GD and the third transfer signal GD have different phases with respect to the reference signal, and the second transfer signal GD and the fourth transfer signal GD have different phases with respect to the reference signal (see FIG. 9).

According to at least one example embodiment, the imaging device 1 includes a third pixel 51 adjacent to the second pixel 51. The third pixel includes a third photoelectric conversion region PD, and fifth and sixth transfer transistors TG0/TG1 coupled to the third photoelectric conversion region PD to transfer charge generated by the third photoelectric conversion region PD. The first driving circuit 310 applies the first transfer signal GD to the fifth transfer transistor TG0 and the second transfer signal GD to the sixth transfer transistor TG1.

According to at least one example embodiment, the imaging device 1 includes a first wiring layer M5 including a first wiring and a second wiring. The first, second, and third pixels 51 are arranged in a column direction in that order, the first wiring extends in the column direction to electrically connect the first transfer transistor to the fifth transfer transistor, and the second wiring extends in the column direction to electrically connect the second transfer transistor to the sixth transfer transistor (see FIG. 7, for example).

According to at least one example embodiment, the imaging device 1 includes a second wiring layer M3 including a third wiring, and the third wiring extends in a row direction to electrically connect the first transfer transistor to a transfer transistor of a neighboring pixel in the row direction (see FIG. 6, for example).

According to at least one example embodiment, the neighboring pixel is an immediately adjacent pixel in the row direction.

According to at least one example embodiment, an intervening pixel is between the first pixel and the neighboring pixel in the row direction (see FIG. 10, for example).

According to at least one example embodiment, the imaging device 1 includes a third wiring layer M6 including a first contact strip that extends in the row direction and that is electrically connected to the second transfer transistor TG1 and the sixth transfer transistor TG1 (see FIG. 8, for example).

According to at least one example embodiment, the third wiring layer M6 includes a second contact strip that extends in the row direction and that is electrically connected to the first transfer transistor TG0 and the fifth transfer transistor TG0.

According to at least one example embodiment, the first contact strip overlaps the first pixel, and the second contact strip overlaps the second pixel (see FIG. 8, for example).

According to at least one example embodiment, the first wiring and the second wiring overlap the first pixel and the second pixel (see FIG. 7, for example).

According to at least one example embodiment, the first mode is a depth mode, and the second mode is a color imaging mode.

According to at least one example embodiment, the reference signal drives a light source in the depth mode.

According to at least one example embodiment, the first driving circuit 310 and the second driving circuit 305 are located on opposite sides of a pixel array including the first pixel.

At least one example embodiment is directed to a system including a light source 5011 that emits light according to a drive signal, and an imaging device 1. The imaging device includes a first pixel 51 including a first photoelectric conversion region PD, first and second transistors TG0/TG1 coupled to the first photoelectric conversion region PD to transfer charge generated by the first photoelectric conversion region PD, and a first driving circuit 310 and a second driving circuit 305 to drive the first pixel 51 in a first mode and a second mode, the first mode being a mode in which the first driving circuit 310 applies a first set of transfer signals GD to the first and second transfer transistors TG0/TG1, the second mode being a mode in which the second driving circuit applies a transfer signal to only one of the first and second transfer transistors TG0 or TG1.

Any processing devices, control units, processing units, etc. discussed above may correspond to one or many computer processing devices, such as a Field Programmable Gate Array (FPGA), an Application-Specific Integrated Circuit (ASIC), any other type of Integrated Circuit (IC) chip, a collection of IC chips, a microcontroller, a collection of microcontrollers, a microprocessor, Central Processing Unit (CPU), a digital signal processor (DSP) or plurality of microprocessors that are configured to execute the instructions sets stored in memory.

As will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “circuit,” “module,” “component,” or “system.” Furthermore, aspects of the present disclosure may take the form of a computer program product embodied in one or more computer readable media having computer readable program code embodied thereon.

Any combination of one or more computer readable media may be utilized. The computer readable media may be a computer readable signal medium or a computer readable storage medium. A computer readable storage medium may be, for example, but not limited to, an electronic, magnetic, optical, electromagnetic, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an appropriate optical fiber with a repeater, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device. Program code embodied on a computer readable signal medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Scala, Smalltalk, Eiffel, JADE, Emerald, C++, C#, VB.NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Aspects of the present disclosure are described herein with reference to flowchart illustrations and/or block diagrams of methods, apparatuses (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable instruction execution apparatus, create a mechanism for implementing the functions/acts specified in the flowchart and/or block diagram block or blocks.

These computer program instructions may also be stored in a computer readable medium that when executed can direct a computer, other programmable data processing apparatus, or other devices to function in a particular manner, such that the instructions when stored in the computer readable medium produce an article of manufacture including instructions which when executed, cause a computer to implement the function/act specified in the flowchart and/or block diagram block or blocks. The computer program instructions may also be loaded onto a computer, other programmable instruction execution apparatus, or other devices to cause a series of operational steps to be performed on the computer, other programmable apparatuses or other devices to produce a computer implemented process such that the instructions which execute on the computer or other programmable apparatus provide processes for implementing the functions/acts specified in the flowchart and/or block diagram block or blocks.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted that the terms “comprising,” “including,” and “having” can be used interchangeably.

The foregoing discussion has been presented for purposes of illustration and description. The foregoing is not intended to limit the disclosure to the form or forms disclosed herein. In the foregoing Detailed Description for example, various features of the disclosure are grouped together in one or more aspects, embodiments, and/or configurations for the purpose of streamlining the disclosure. The features of the aspects, embodiments, and/or configurations of the disclosure may be combined in alternate aspects, embodiments, and/or configurations other than those discussed above. This method of disclosure is not to be interpreted as reflecting an intention that the claims require more features than are expressly recited in each claim. Rather, as the following claims reflect, inventive aspects lie in less than all features of a single foregoing disclosed aspect, embodiment, and/or configuration. Thus, the following claims are hereby incorporated into this Detailed Description, with each claim standing on its own as an embodiment of the disclosure.

Moreover, though the description has included description of one or more aspects, embodiments, and/or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and/or configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

Example embodiments may be configured according to the following:

(1) An imaging device, comprising:

a first pixel, including:
a first photoelectric conversion region; and
first and second transistors coupled to the first photoelectric conversion region to transfer charge generated by the first photoelectric conversion region; and

a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

(2) The imaging device of (1), wherein the first set of transfer signals include a first transfer signal applied to the first transfer transistor, and a second transfer signal applied to the second transfer transistor, and wherein the first transfer signal and the second transfer signal have different phases with respect to a reference signal.
(3) The imaging device of one or more of (1) to (2), further comprising:

a second pixel adjacent to the first pixel and including:
a second photoelectric conversion region; and
third and fourth transfer transistors coupled to the second photoelectric conversion region to transfer charge generated by the second photoelectric conversion region, wherein the first driving circuit applies a second set of transfer signals to the third and fourth transfer transistors.
   (4) The imaging device of one or more of (1) to (3), wherein the second set of transfer signals include a third transfer signal applied to the third transfer transistor, and a fourth transfer signal applied to the fourth transfer transistor, and wherein third transfer signal and the fourth transfer signal have different phases with respect to the reference signal.
   (5) The imaging device of one or more of (1) to (4), wherein the second pixel is adjacent to the first pixel in a row direction, wherein the first transfer signal and the third transfer signal have a same phase with respect to the reference signal, and the second transfer signal and the fourth transfer signal have a same phase with respect to the reference signal.
   (6) The imaging device of one or more of (1) to (5), wherein the second pixel is adjacent to the first pixel in a row direction, wherein the first transfer signal and the third transfer signal have different phases with respect to the reference signal, and the second transfer signal and the fourth transfer signal have different phases with respect to the reference signal.
   (7) The imaging device of one or more of (1) to (6), further comprising:

a third pixel adjacent to the second pixel and including:
a third photoelectric conversion region; and
fifth and sixth transfer transistors coupled to the third photoelectric conversion region to transfer charge generated by the third photoelectric conversion region, wherein the first driving circuit applies the first transfer signal to the fifth transfer transistor and the second transfer signal to the sixth transfer transistor.
   (8) The imaging device of one or more of (1) to (7), further comprising:

a first wiring layer including a first wiring and a second wiring, wherein the first, second, and third pixels are arranged in a column direction in that order, and wherein the first wiring extends in the column direction to electrically connect the first transfer transistor to the fifth transfer transistor, and wherein the second wiring extends in the column direction to electrically connect the second transfer transistor to the sixth transfer transistor.

(9) The imaging device of one or more of (1) to (8), further comprising:

a second wiring layer including a third wiring, wherein the third wiring extends in a row direction to electrically connect the first transfer transistor to a transfer transistor of a neighboring pixel in the row direction.

(10) The imaging device of one or more of (1) to (9), wherein the neighboring pixel is an immediately adjacent pixel in the row direction.
(11) The imaging device of one or more of (1) to (10), wherein an intervening pixel is between the first pixel and the neighboring pixel in the row direction.
(12) The imaging device of one or more of (1) to (11), further comprising:

a third wiring layer including a first contact strip that extends in the row direction and that is electrically connected to the second transfer transistor and the sixth transfer transistor.

(13) The imaging device of one or more of (1) to (12), wherein the third wiring layer includes a second contact strip that extends in the row direction and that is electrically connected to the first transfer transistor and the fifth transfer transistor.
(14) The imaging device of one or more of (1) to (13), wherein the first contact strip overlaps the first pixel, and wherein the second contact strip overlaps the second pixel.
(15) The imaging device of one or more of (1) to (14), wherein the first wiring and the second wiring overlap the first pixel and the second pixel.
(16) The imaging device of one or more of (1) to (15), wherein the first mode is a depth mode, and the second mode is a color imaging mode.
(17) The imaging device of one or more of (1) to (16), wherein the reference signal drives a light source in the depth mode.
(18) The imaging device of one or more of (1) to (17), wherein the first driving circuit and the second driving circuit are located on opposite sides of a pixel array including the first pixel.
(19) A system, comprising:

a light source that emits light according to a drive signal;

an imaging device, comprising:
a first pixel, including:
   a first photoelectric conversion region;
   first and second transistors coupled to the first photoelectric conversion region to transfer charge generated by the first photoelectric conversion region; and
a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.
   (20) An imaging device, comprising:

a pixel array including a first pixel, the first pixel including:
a first photoelectric conversion region; and
first and second transistors coupled to the first photoelectric conversion region to transfer charge generated by the first photoelectric conversion region; and

a first driving circuit and a second driving circuit located on opposite sides of the pixel array to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

Any one or more of the aspects/embodiments as substantially disclosed herein.

Any one or more of the aspects/embodiments as substantially disclosed herein optionally in combination with any one or more other aspects/embodiments as substantially disclosed herein.

One or more means adapted to perform any one or more of the above aspects/embodiments as substantially disclosed herein.

It is claimed:

1. An imaging device, comprising:
a first pixel, including:
a first photoelectric conversion region; and
first and second transistors coupled to the first photoelectric conversion region to transfer charge generated by the first photoelectric conversion region; and
a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

2. The imaging device of claim 1, wherein the first set of transfer signals include a first transfer signal applied to the first transfer transistor, and a second transfer signal applied to the second transfer transistor, and wherein the first transfer signal and the second transfer signal have different phases with respect to a reference signal.

3. The imaging device of claim 2, further comprising:
a second pixel adjacent to the first pixel and including:
a second photoelectric conversion region; and
third and fourth transfer transistors coupled to the second photoelectric conversion region to transfer charge generated by the second photoelectric conversion region, wherein the first driving circuit applies a second set of transfer signals to the third and fourth transfer transistors.

4. The imaging device of claim 3, wherein the second set of transfer signals include a third transfer signal applied to the third transfer transistor, and a fourth transfer signal applied to the fourth transfer transistor, and wherein third transfer signal and the fourth transfer signal have different phases with respect to the reference signal.

5. The imaging device of claim 4, wherein the second pixel is adjacent to the first pixel in a row direction, wherein the first transfer signal and the third transfer signal have a same phase with respect to the reference signal, and the second transfer signal and the fourth transfer signal have a same phase with respect to the reference signal.

6. The imaging device of claim 4, wherein the second pixel is adjacent to the first pixel in a row direction, wherein the first transfer signal and the third transfer signal have different phases with respect to the reference signal, and the second transfer signal and the fourth transfer signal have different phases with respect to the reference signal.

7. The imaging device of claim 4, further comprising:
a third pixel adjacent to the second pixel and including:
a third photoelectric conversion region; and
fifth and sixth transfer transistors coupled to the third photoelectric conversion region to transfer charge generated by the third photoelectric conversion region, wherein the first driving circuit applies the first transfer signal to the fifth transfer transistor and the second transfer signal to the sixth transfer transistor.

8. The imaging device of claim 7, further comprising:
a first wiring layer including a first wiring and a second wiring, wherein the first, second, and third pixels are arranged in a column direction in that order, and wherein the first wiring extends in the column direction to electrically connect the first transfer transistor to the fifth transfer transistor, and wherein the second wiring extends in the column direction to electrically connect the second transfer transistor to the sixth transfer transistor.

9. The imaging device of claim 8, further comprising:
a second wiring layer including a third wiring, wherein the third wiring extends in a row direction to electrically connect the first transfer transistor to a transfer transistor of a neighboring pixel in the row direction.

10. The imaging device of claim 9, wherein the neighboring pixel is an immediately adjacent pixel in the row direction.

11. The imaging device of claim 9, wherein an intervening pixel is between the first pixel and the neighboring pixel in the row direction.

12. The imaging device of claim 9, further comprising:
a third wiring layer including a first contact strip that extends in the row direction and that is electrically connected to the second transfer transistor and the sixth transfer transistor.

13. The imaging device of claim 12, wherein the third wiring layer includes a second contact strip that extends in the row direction and that is electrically connected to the first transfer transistor and the fifth transfer transistor.

14. The imaging device of claim 13, wherein the first contact strip overlaps the first pixel, and wherein the second contact strip overlaps the second pixel.

15. The imaging device of claim 14, wherein the first wiring and the second wiring overlap the first pixel and the second pixel.

16. The imaging device of claim 1, wherein the first mode is a depth mode, and the second mode is a color imaging mode.

17. The imaging device of claim 16, wherein the reference signal drives a light source in the depth mode.

18. The imaging device of claim 1, wherein the first driving circuit and the second driving circuit are located on opposite sides of a pixel array including the first pixel.

19. A system, comprising:
a light source that emits light according to a drive signal;
an imaging device, comprising:
a first pixel, including:
a first photoelectric conversion region;
first and second transistors coupled to the first photoelectric conversion region to transfer charge generated by the first photoelectric conversion region; and
a first driving circuit and a second driving circuit to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.

20. An imaging device, comprising:
a pixel array including a first pixel, the first pixel including:
a first photoelectric conversion region; and
first and second transistors coupled to the first photoelectric conversion region to transfer charge generated by the first photoelectric conversion region; and
a first driving circuit and a second driving circuit located on opposite sides of the pixel array to drive the first pixel in a first mode and a second mode, the first mode being a mode in which the first driving circuit applies a first set of transfer signals to the first and second transfer transistors, the second mode being a mode in which the second driving circuit applies a transfer signal to only one of the first and second transfer transistors.
